(19) United States
(12) Patent Application Publication
(10) Pub. No.: US 2006/0279748 A1
(43) Pub. Date: Dec. 14, 2006

(54) Apparatus and method for compensating for resolution differences of color and monochrome sensors

(75) Inventor: Yoshikatsu Kamisuwa, Tokyo (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/147,461

(22) Filed: Jun. 8, 2005

(51) Int. Cl. G06K 15/02; G03F 3/08

(52) U.S. Cl. 358/1.2; 358/1.9; 358/518

(57) ABSTRACT

An apparatus and method for processing image data includes generating color image data and monochrome image data from an original image, the color image data and the monochrome image data having a first resolution, the color image data including RGB data. Multiples of pixels of the color image data are averaged such that the averaged pixel data has a second resolution lower than the first resolution based on the multiples. Color difference data is generated using the averaged pixel data, and compensated color image data is generated having the first resolution based on the color difference data and the monochrome image data.

### FIELD OF THE INVENTION

The present invention relates generally to image processing and, more particularly, to a system and method for compensating for resolution differences of color and monochrome sensors.

### BACKGROUND OF THE INVENTION

To perform color copying, a copying machine or multi-function peripheral (MFP) typically includes a 1-dimensional image-sensor having either a three-line charge-coupled device (CCD) or a four-line CCD. The three-line CCD includes sensors for the three primary colors red (R), green (G), and blue (B). More specifically, the three-line CCD includes photodiode arrays for R, G, and B. Each array includes a predetermined number of photodiodes arranged in the main scanning direction, each photodiode corresponding to a pixel. Each photodiode accumulates charge according to a quantity of light received. The four-line CCD includes sensors for the three primary colors R, G, and B, as well as one for monochrome or black/white (B/W).

In general, the color sensors have a lower sensitivity than the monochrome sensor. As a result, if the color sensors are read at the same rate or speed as the monochrome sensor, more noise is generated by the color sensors as compared to the monochrome sensor, which worsens the signal-to-noise ratio (SNR). To compensate for this problem, conventional image reading devices either use a very low reading speed, or the pixel size (i.e., the size of the photodiode) of the color sensor is made larger than the monochrome sensor in order to receive more light. By using a lower reading speed, the processing speed of the image reading device is diminished. In addition, using a larger pixel size increases the size of the color sensor and the image reading device. In addition, a larger pixel size is more expensive to produce and use.

### SUMMARY OF THE INVENTION

According to an aspect of the invention, an image forming apparatus and method for processing image data includes generating color image data and monochrome image data from an original image, the color image data and the monochrome image data having a first resolution, the color image data including RGB data. Multiples of pixels of the color image data are averaged such that the averaged pixel data has a second resolution lower than the first resolution based on the multiples. Color difference data is generated using the averaged pixel data, and compensated color image data is generated having the first resolution based on the color difference data and the monochrome image data.

Further features, aspects and advantages of the present invention will become apparent from the detailed description of preferred embodiments that follows, when considered together with the accompanying figures of drawing.

### BRIEF DESCRIPTION OF THE DRAWINGS

FIG. 1 is a frontal outline view of an image forming apparatus in consistent with the present invention.

FIG. 2 is a partial cut-way side-view of the image forming apparatus of FIG. 1.

FIG. 3 is a block diagram of an image reading apparatus consistent with the present invention.

FIG. 4 is a block diagram of an image sensor unit consistent with the present invention.

FIG. 5 is a block diagram of a color signal correction unit consistent with the present invention.

FIG. 6 is a schematic explanatory diagram of an image sensor unit consistent with the present invention.

FIG. 7A is an alternative arrangement of photodiode arrays of an image sensor unit consistent with the present invention.

FIG. 7B is a graphical illustration of color pixel equalization using the alternative arrangement of photodiode arrays shown in FIG. 7A.

FIG. 8 is a block diagram of another color signal correction unit consistent with the present invention.

### DETAILED DESCRIPTION OF PREFERRED EMBODIMENTS

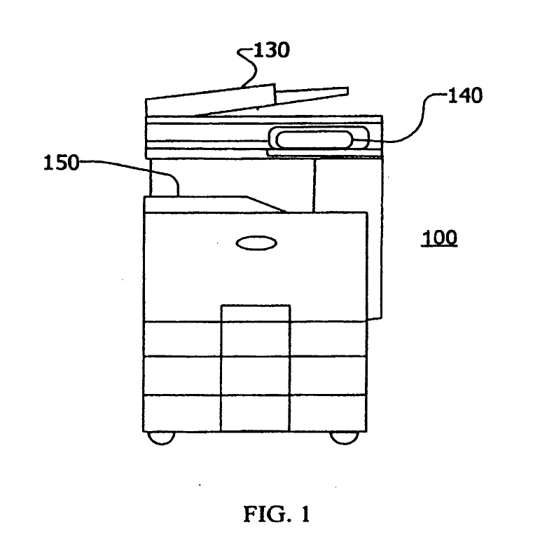

Referring now to FIG. 1, there is shown a frontal outline view of an image forming apparatus 100 consistent with the present invention. The image forming apparatus 100 may be, for example, a copier, fax, printer or multi-function peripheral (MFP). The image forming apparatus 100 may form the image on such media as paper or overhead transparencies.

The image forming apparatus 100 is one type of an image reading apparatus. As used herein, and “image reading apparatus” is an electronic device which forms images. An image reading apparatus may also be a still camera, video camera, telescope, scanner, bar code reader, robot having machine vision, or other device which incorporates an image sensor.

The image forming apparatus 100 has an input feeder 130, an operation element 140 and an output tray 150. the input feeder 130, the operation element 140 and the output tray 150 may be configured as those known in the art.

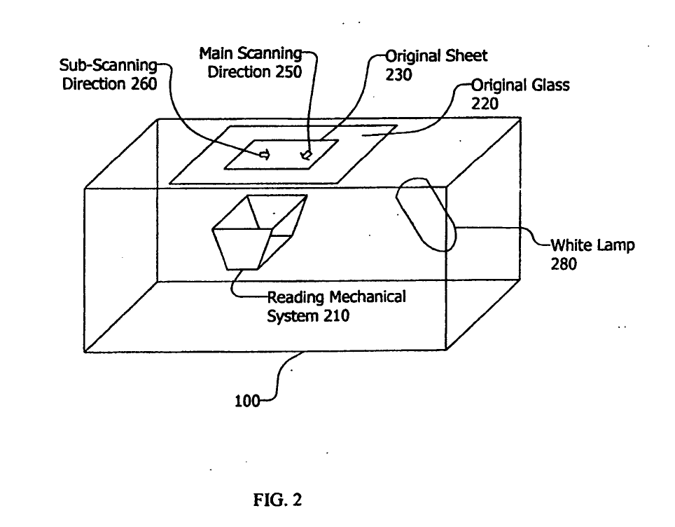

Referring now to FIG. 2, there is shown a partial cut-way side-view of the image forming apparatus of FIG. 1 having an original sheet (e.g., of paper) 230 disposed on an original glass 220. The image forming apparatus 100 further includes a reading mechanical system 210 and a white lamp 280. the white lamp 280 is disposed opposite the original glass 220 from the original sheet 220.

The original sheet 230 may have an image disposed thereon, such as text or graphics. The original sheet 230 is moved onto the original glass 220. The white lamp 280 illuminates the original sheet 230. The reading mechanical system 210 generates signals corresponding to the image on the original sheet 230.

To generate signals for the entire image on the original sheet 230, there may be a scanning process. For example, the reading mechanical system 210 may scan the original sheet 230 one line at a time. The reading mechanical system 210 may include a one-dimensional image sensor unit. By using a two-dimensional image sensor unit in the reading mechanical system 210, it may be possible to scan images on the original sheet 230 with no or little movement. Furthermore, multi-dimensional image sensor units may be provided, for example for scanning three-dimensional and complex objects.

There may be a main scanning direction 250 and a sub-scanning direction 260. The main scanning direction 250 may follow the axial direction of a photosensitive drum in the image forming apparatus 100. The sub-scanning direction 260 may follow the rotation direction of the photosensitive drums, and may be perpendicular to the main scanning direction 250. The original sheet 230, reading mechanical system 210 and/or intermediate optics may have mechanical motion to allow complete scanning. Thus, there may be mechanical motion in the main scanning direction 250 and in the sub-scanning direction 260. This motion may be by the entire reading mechanical system 210 or by one or more parts. This motion may be at one or more fixed or variable speeds.

Where the image reading apparatus is other than an image forming apparatus, the image reading apparatus may be used for reading an image of a solid or flat object. The solid or flat object may be located proximate the image reading apparatus or at a distance from the image reading apparatus. The image reading apparatus may include a light source, such as the white lamp 280 of the image forming apparatus 100. Alternatively, the objection may be illuminated from an external light source or ambient light.

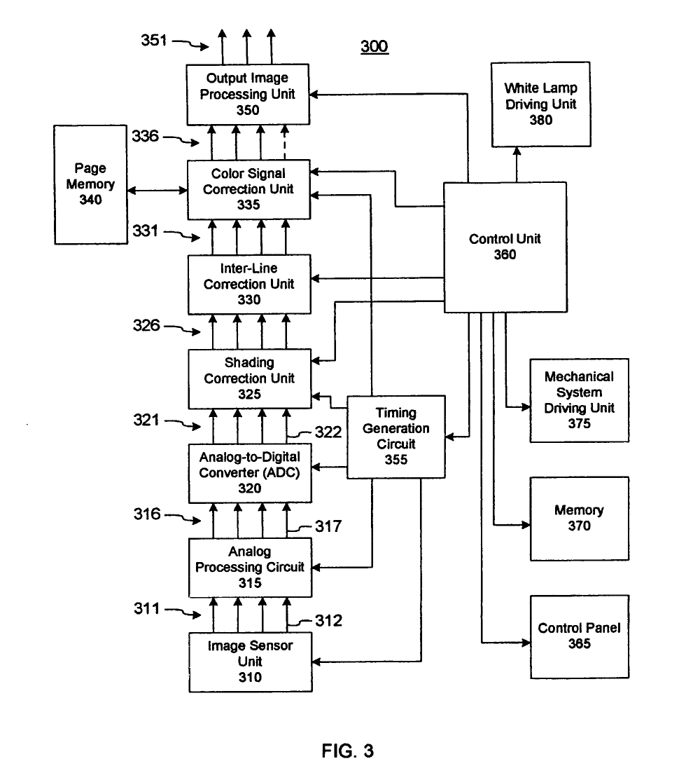

Referring now to FIG. 3, there is shown a block diagram of an image reading apparatus 300 consistent with the present invention. The image reading apparatus 300 includes portions designed for image processing and portions designed for control. The image processing portions include an image sensor unit 310, an analog processing unit 315, an analog-to-digital conversion circuit (ADC) 320, a shading correction unit 325, an inter-line correction circuit 330, a color signal correction unit 335, a page memory 340, and an output image processing unit 350. The control portions include a timing generation circuit 355, a control unit 360, a memory 370, a control panel 365, a mechanical system driving unit 375, and a white lamp driving unit 380.

The image reading apparatus 300 includes hardware and may include software, altogether for providing the functional and features described below. The image reading apparatus 300 may include one or more of: logic arrays, memories, analog circuits, digital circuits, software, firmware, and processors such as microprocessors, field programmable gate arrays (FPGAs), application specific integrated circuits (ASICs), programmable logic devices (PLDs) and programmable logic arrays (PLAs). The hardware and firmware components of the image reading apparatus 300 may include various specialized units, circuits, software, and interfaces for providing the functionality and features described below.

The image sensor unit 310 may generate color signals and monochrome signals and output them on color channels 311 and monochrome channel 312. The image sensor unit 310 may be included in the reading mechanical system 210 (FIG. 2). The image sensor unit 310 may be or include a 4-line CCD or other arrays of photodiodes. The color signals may be formed in one channel for each color such as each of the three primary colors R, G, and B. The monochrome signal may be formed in one monochrome channel. The color signals and the monochrome signal may be output simultaneously, such as in parallel, or they may be switched. The image sensor unit 310 may be embodied as one or more integrated circuit chips. The image sensor unit 310 may include or be used in conjunction with color filters arranged with respect to the CCDs for each color.

As used herein, a “charge-coupled device” or “CCD” is a light sensitive integrated circuit that produces and stores (generally temporarily) electric charges representing light levels to which the CCD is exposed. A CCD may be formed of an array of photodiodes to thereby provide a representation of an image to which the CCD is exposed. The array may be one- or multi-dimensional. A “photodiode” is a semiconductor diode that generates an electric signal when exposed to light. The photodiodes of a CCD may have particular sensitivities, such as for particular light frequencies or levels.

The analog processing unit 315 receives the color signals on the color channels 311, and the monochrome signals on the monochrome channel 312. The analog processing unit 315 processes the color and monochrome signals from the image sensor unit 310 so that they are suitable for conversion to digital signals. The analog processing unit 315 may perform such processing as level shifting, removal of nozzle component, and amplification. To perform this processing, the analog processing unit 315 may include one or more of: a coupling capacitor, a correlated double-sampling (CDS) circuit, a sample and hold circuit, a gain amplifier, and an offset removal circuit. The analog processing unit 315 outputs the processed color signals on the color channels 316, and the monochrome signals on the monochrome channel 317.

The ADC 320 receives the processed color signals on the color channels 316 and the monochrome signals on the monochrome channel 317. The ADC 320 converts the processed color signals into digital signals for output on channels 321. The ADC 320 also converts the processed monochrome signal into a digital monochrome signal for output on a channel 322.

The shading correction unit 325 receives the digital signals from ADC 320 on the channels 321, 322. The shading correction unit 325 corrects the digital signals for variations of sensitivity of the photodiodes in the image sensor unit 310 and illumination. There may be variations in the illumination of the object, and it may be desirable to correct for these variations, especially in the main scanning direction 250. The shading correction unit 325 outputs signals on channels 326, wherein there may be one channel each for the three primary colors and monochrome.

The arrays of photodiodes in the image sensor unit 310 may have differences in position which can give rise to misalignment of the read image. The inter-line correction circuit 330 corrects the color and monochrome signals for these differences in position. The inter-line correction circuit 330 receives signals on the channels 326 and outputs signals on the channels 331.

The page memory 340 may store the read image signals, which the page memory 340 may receive from the color signal correction unit 335 via channel 341. In the color imaging mode, the page memory 340 may store corrected read image signals. In monochrome mode, the page memory 340 may store uncorrected read image signals.

The output image processing unit 350 provides the final image output of the image reading apparatus 300. The output image processing unit 350 is an interface to an output destination, and may convert signals according to the needs of the output destination. For example, the output image processing unit 350 may change the range of a gamma control according to devices such as a display or printer. The output image processing unit 350 receives color and monochrome signals on channels 336 and outputs processed signals on channels 351. Although the color and monochrome signals received by the output image processing unit 350 come from the color signal correction unit 335, these signals may be obtained directly from the color signal correction unit 335 or indirectly from the page memory 340.

The timing generation circuit 355, under the control of the control unit 360, generates and provides timing signals to the image sensor unit 310, the analog processing unit 315, the ADC 320, the shading correction unit 325, the inter-line correction circuit 330, the color signal correction unit 335, and the page memory 340.

The control unit 360 may control the image reading apparatus 300 according to programs and data stored in the memory 370. The control unit 360 may use the memory 370 as a working memory.

The memory 370 provides long term and short term storage of data and programs for the image reading apparatus 300. The memory 370 may be combined with the page memory 340. The memory 370 may not be expandable or difficult to expand, whereas the page memory 340 may be designed for expandability.

The control panel 365 receives input information by a user. This input information may include the operation mode (e.g., color or monochrome mode) and a selected number of printing sheets of paper.

The mechanical system driving unit 375 operates under control of the control unit 360. The mechanical system driving unit 375 drives a moving mechanism in the sub-scanning direction 260. The moving speed of the moving mechanism in the sub-scanning direction 260 may be the same in color mode and monochrome mode. In such a case, the mechanical system driving unit 375 performs the driving operation without regard to the color mode and monochrome mode.

The white lamp driving unit 380 drives a white lamp, which may irradiate white light to an object such as a document. The white lamp driving unit 380 operates under control of the control unit 360.

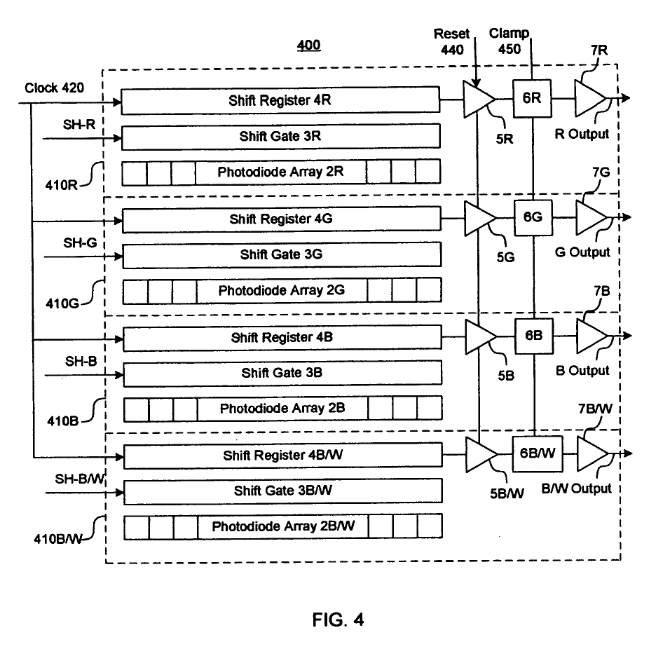

Referring now to FIG. 4, there is shown a block diagram of an image sensor unit 400. The image sensor unit 400 may be used as the image sensor unit 310 of FIG. 3. The image sensor unit 400 is a 4-line type, and includes three photoelectric converters 410R, 410G, 410B for color and one photoelectric converter 410B/W for monochrome. The letters R, G, B, and B/W refer to the respective color: red, green, blue, and monochrome (black/white).

The photoelectric converters 410R, 410G, 410B, 410B/W each have a single linear (one-dimensional) photodiode array 2R, 2G, 2B, 2B/W, comprising a number of photodiodes. Each photodiode of the photodiode arrays 2R, 2G, 2B, 2B/W has a sequential reference number from some arbitrary starting point in the respective array. Accordingly, based upon its reference number, a photodiode may be referred to as “odd” or “even.” The photodiodes of the photodiode arrays 2R, 2G, 2B, 2B/W may be arranged in the main scanning direction 250. The photodiodes store (photoelectrically convert) charges according to a received quantity of light. The photodiodes may be adapted to be sensitive to predetermined frequencies.

The photodiode arrays 2R, 2G, 2B, 2B/W may be rectilinear, have a uniform length and width, and be aligned in the main scanning direction. The order of the four kinds of photodiode arrays 2R, 2G, 2B, 2B/W in the sub-scanning direction is optional. However, to obtain better balance of the three color outputs (R Output, G Output, B Output), it is preferable for the monochrome photodiode array 2B/W to be positioned at an end (on the uppermost part or lowermost part shown in FIG. 4) of the photodiode arrays 2R, 2G, 2B instead of between them. FIG. 4 shows a case that the monochrome photodiode array 2B/W is in the lowermost position.

The photodiode arrays 2R, 2G, 2B, 2B/W may be spaced at respective intervals and disposed in positions relative to one another as shown. In the sub-scanning direction, the intervals between the center lines of the photodiode arrays 2R, 2G, 2B, 2B/W may be an integral multiple of the reading pitch. The reading pitch may be determined by the product of the moving speed of a carriage of a scanner in the reading mechanical system 210 (FIG. 2) and the period of time of SH-R, SH-G, SH-B, and SH-B/W.

As shown in FIG. 4, the photodiode arrays 2R, 2G, 2B, 2B/W include a number of photodiodes (i.e., each box in each array), where each photodiode corresponds to a pixel. Although the figures may appear to shown the photodiode arrays 2R, 2G, 2B, 2B/W each having a large central portion, this is intended to represent an undefined number of photodiodes. The photodiodes have respective light receiving surfaces. The light receiving surfaces of the photodiodes W may have a uniform height and width. The size and shape of the light receiving area may be one determinant of a photodiode's sensitivity. The area of the color and monochrome photodiodes may be the same. It is also possible for the color photodiodes to be larger than the monochrome photodiodes.

In the embodiment as shown in FIG. 4, all of the photodiodes are the same size and each of the photodiode arrays 2R, 2G, 2B, 2B/W has the same number of photodiodes. Because of the relative sizes of the area of the photodiodes and because of the timing of the output signals, the resolution of the monochrome output signal BAN Output is equal to the resolution of the color output signals R Output, G Output, B Output in both the main scanning direction and the sub-scanning direction.

In FIG. 4, the color photoelectric converters 410R, 410G, 410B respectively have shift gates 3R, 3G, 3B, shift registers 4R, 4G, 4B, reset gates 5R, 5G, 5B, clamp circuits 6R, 6G, 6B, and amplifiers 7R, 7G, 7B. The monochrome photoelectric converter 410B/W shift gate 3B/W, shift register 4B/W, reset gate 5B/W, clamp circuit 6B/W, and amplifier 7B/W.

The stored charges of the photodiode arrays 2R, 2G, 2B, are shifted to the corresponding shift registers 4R, 4G, 4B via the shift gates 3R, 3G, 3B which are put into open state according to shift signals SH-R, SH-G, SH-B. The stored charges of the photodiode array 2B/W is shifted to the corresponding shift register 4B/W via the shift gate 3B/W, which is put into an open state according to shift signal SH-B/W. The shift signals SH-R, SH-G, and SH-B may be the same. The shift signal SH-B/W may have a cycle which is equal to the cycle of the shift signals SH-R, SH-G, SH-B. The shift registers 4R, 4G, 4B, 4B/W may be CCD analog shift registers.

To the respective shift registers 4R, 4G, 4B, 4B/W, the stored charges of the photodiodes arrays 2R, 2G, 2B, 2B/W are shifted according to a predetermined timing. The respective shift registers 4R, 4G, 4B, 4B/W may output the shifted stored charges at respective serial signals (a one-dimensional image signal) according to a single clock signal 420. In this case, in order to prevent the output signals from interfering, a reset signal 440 may be provided via the reset gates 5R, 5G, 5B, 5B/W. Thereafter, the output signals are clamped by the clamp circuits 6R, 6G, 6B, 6B/W in response to a clamp signal 450 and amplified and outputted by the corresponding amplifiers 7R, 7G, 7B, 7B/W.

In operation, in response to a command from the control panel 365 to read an original in color mode, the control unit 360 turns on the white lamp driving unit 380 and drives the read mechanism by the mechanical system driving unit 375. In addition, the control unit 360 starts various elements of image reading apparatus 300 including the image sensor unit 310, the analog processing circuit 315, the ADC 320, the shading correction unit 325, the inter-line correction unit 330, the color signal correction unit 335, and the page memory 340, indirectly or directly through the timing generating circuit 355.

The timing generating circuit 355 provides the shift command signals SH-R, SH-G, SH-B, SH-B/W, the clock signal 420, the reset signal 440, and the clamp signal 450 as shown in FIG. 4. In the image sensor unit 310 (or image sensor unit 400 of FIG. 4), the electric charge accumulated in the photodiode arrays 2R, 2G and 2B for the three primary colors R, G and B by photoelectric conversion is transferred to shift registers 4R, 4G and 4B through the shift gates 3R, 3G and 3B according to shift command signals SH-R, SH-G and SH-B, and serially outputted from the shift registers 4R, 4G and 4B while the photodiode arrays 2R, 2G, 2B are charging electricity for the next photoelectric conversion according to the clock signal 420. Then, it is provided to the analog processing circuit 315 sequentially through the reset gates 5R, 5G and 5B, the clamping circuits 6R, 6G and 6B, and the amplifiers 7R, 7G and 7B.

Similarly, the electric charge accumulated by photoelectric conversion in the photodiode array 2B/W for the monochrome data is transferred to the shift register 4B/W through the shift gate 3B/W according to the shift command signal SH-B/W, and serially outputted from the shift register 4B/W while the photodiode array 2B/W is charging electricity for the next photoelectric conversion according to the clock signal 420. Then, it is provided to the analog processing circuit 315 sequentially through the reset gate 5B/W, the clamping circuit 6B/W, and the amplifier 7B/W.

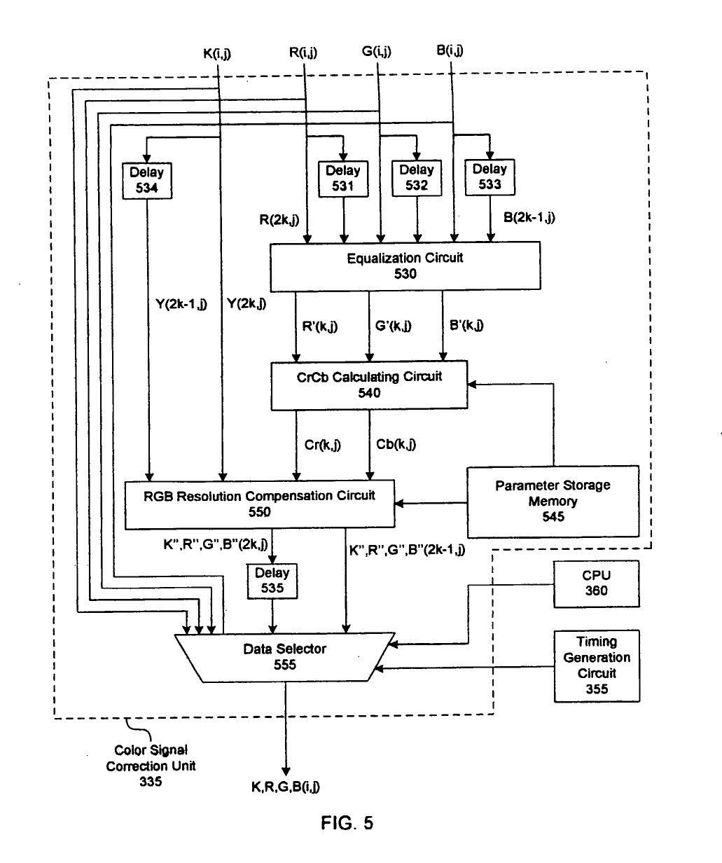

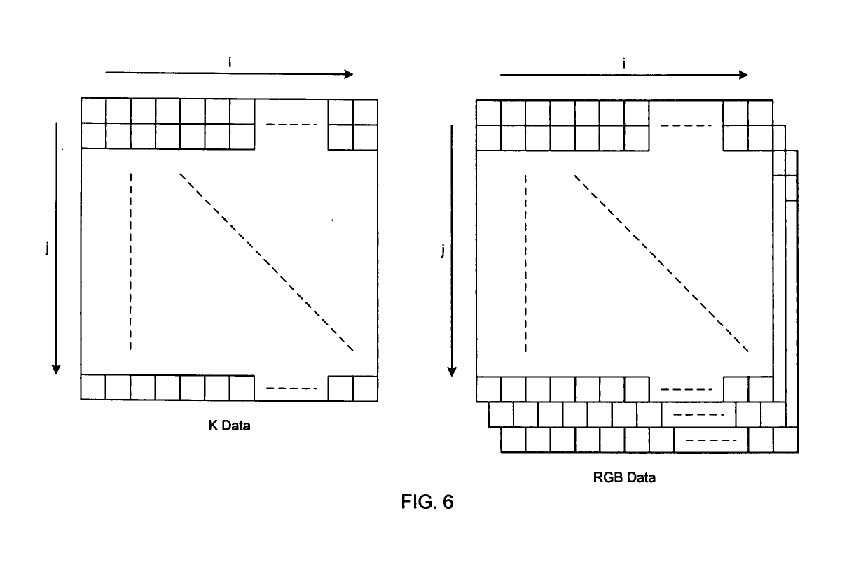

Referring now to FIG. 5, there is shown a block diagram of a color signal correction unit consistent with the present invention. FIG. 6 is a schematic explanatory diagram of an image sensor unit consistent with the present invention. Monochrome signals and color signals represented by the same number of bits are input to the color signal correction unit 335.

In FIG. 5, the color signal correction unit 335 includes an equalization circuit 530, a CrCb calculating circuit 540, an RGB resolution compensation circuit 550, a parameter storage memory 545, one-pixel delays 531-535, and a data selector 555.

The color signal correction unit 335 receives the monochrome pixel data K(i,j) and the color pixel data R(i,j), G(i,j), B(i,j) in parallel, where i and j correspond to the column and row of the pixel in the monochrome and color pixel data. In the following formulas, the variable k also refers to the column of the pixel in the monochrome and color pixel data. The row of each pixel corresponds to the main scanning direction 250, and the column corresponds to the sub-scanning direction 260.

The equalization circuit 530, in conjunction with the 1-pixel delay buffers 531-533, perform the equalization processes shown in formulas (1) to (3). In particular, the equalization circuit 530 converts each of the three primary colors pixel data R(i,j), G(i,j) and B(i,j) into the average of each pair of adjacent pixels R′(k,j), G′(k,j) and B′(k,j) in accordance with the following formulas (1) to (3):
R′(k,j)=(R(2k−1,j)+R(2k,j))/2 (1)
G′(k,j)=(G(2k−1,j)+G(2k,j))/2 (2)
B′(k,j)=(B(2k−1,j)+B(2k,j))/2 (3)

This equalization process essentially averages adjacent pixels such as R₁′=(R₁+R₂)/2 and R₂′=(R₃+R₄)/2, etc., and can improve the S/N ratio of the color pixel data, which is lowered by the shortage of luminous energy. However, with this equalization process, the resolution of the color pixel data is reduced by one half (e.g., from 600 dpi to 300 dpi), and the total number of pixels in the color pixel data is also reduced by one half.

The CrCb calculation circuit 540, in conjunction with the 1-pixel delay buffer 534, perform a YCrCb conversion in accordance with the formulas (4) to (7), and the outputs from the CrCb calculation circuit 540 and the 1-pixel delay buffer 534 are provided to the RGB resolution compensation circuit 550.
Y(2k−1,j)=K(2k−1,j) (4)
Y(2k,j)=K(2k,j) (5)
Cr(k,j)=aᵣ₀R′(k,j)+a_{g0}G′(k,j)+a_{b0}B′(k,j) (6)
Cb(k,j)=aᵣ₁R′(k,j)+a_{g1}G′(k,j)+a_{b1}B′(k,j) (7)

In particular, the data is converted by into a luminance signal (Y), a first color-difference signal Cr (R-Y component), and a second color-difference signal Cb (B-Y component). The CrCb calculation circuit 540 uses the color pixel data R′(k,j), G′(k,j), B′(k,j) and the parameters aᵣ₀, a_{g0}, a_{b0}, aᵣ₁, a_{g1}, and a_{b1} stored in the parameter storage memory 545.

Since the B/W signal K can be treated as a luminance signal Y as it is, the inputted B/W signal K(i,j) can be inputted into the RGB resolution compensation circuit 550 as the luminance signal Y(2k,j), which corresponds to formula (5), and the luminance signal Y(2k−1,j) corresponding to formula (4) can be inputted into the RGB resolution compensation circuit 550 by delaying the inputted B/W signal K(i,j) for 1-pixel length via the 1-pixel delay buffer 534.

The first color-difference signal Cr and the second color-difference signal Cb can be formed from a signal of the three primary colors (R, G, B) as shown in formulas (6) and (7), even if there is no luminance signal. By calculating formulas (6) and (7) using the parameters aᵣ₀, a_{g0}, a_{b0}, aᵣ₁, a_{g1}, and a_{b1} stored in the parameter storage memory 545, the CrCb calculating circuit 540 obtains the pixel data Cr(k,j) of the first color-difference signal and the pixel data Cb(k, j) of the second color-difference signal, and inputs them into the RGB resolution compensation circuit 31. The data output from the CrCb calculating circuit 540 has the same resolution as the color pixel data R′(k,j), G′(k,j), B′(k,j).

The RGB resolution compensation circuit 550 executes RGB inverse transformation according to formulas (8)-(13) using the parameters bₖ₀, bₖ₁, bₖ₂, bᵣ₀, bᵣ₁, b_{b0}, b_{b1} stored in the parameter storage memory 545 to obtain the three primary colors, R″, G″ and B″, in which the resolution (number of pixel) is improved.
R″(2k−1,j)=bₖ₀K(2k−1,j)+bᵣ₀Cr(k,j) (8)
G″(2k−1,j)=bₖ₁K(2k−1,j)−bᵣ₁Cr(k,j)+b_{b0}Cb(k,j) (9)
B″(2k−1,j)=bₖ₂K(2k−1,j)+b_{b1}Cb(k,j) (10)
R″(2k,j)=bₖ₀K(2k,j)+bᵣ₀Cr(k,j) (11)
G″(2k,j)=bₖ₁K(2k,j)−bᵣ₁Cr(k,j)+b_{b0}Cb(k,j) (12)
B″(2k,j)=bₖ₂K(2k,j)+b_{b1}Cb(k,j) (13)

The luminance signal (Y=K), the first color-difference signal (Cr), and the second color-difference signal (Cb) can be converted into the three-primary-colors signal R″, G″ and B″. The number of pixels of the luminance signal (Y=K) in the main scanning direction is twice the number of pixels of the first color-difference signal (Cr) and the second color-difference signal (Cb) in the main scanning direction. Using the formulas (8) to (13), the RGB resolution compensation circuit 550 restores the number of pixels of the three-primary-colors signal R″, G″ and B″ in the main scanning direction after conversion to the same number of pixels before the equalization performed by the equalization circuit 530.

The formulas (8)-(10) calculate the converted three-primary-colors signal R″, G″ and B′ at the odd-numbered pixel position. The formulas (11)-(13) calculate the converted three-primary-colors signal R″, G″ and B″ at the even-numbered pixel position. The RGB resolution compensation circuit 550 may calculate these formulas (8)-(13) almost or essentially in parallel using the parameters bₖ₀, bₖ₁, bₖ₂, bᵣ₀, bᵣ₁, b_{b0}, and b_{b1} that are stored in the parameter storage memory 545.

The RGB resolution compensation circuit 550 provides the three primary color signals R″(2k−1,j), G″(2k−1,j), and B″(2k−1,j) at the odd-numbered pixel position to the data selector 555 as a first selection input, and provides the three primary color signals R″(2k,j), G″(2k,j), and B″(2k,j) at the even-numbered pixel position to the data selector 555 as a second selection input by delaying for 1-pixel length via the 1-pixel delay buffer 535.

FIG. 5 shows the case where a luminance signal, i.e. B/W signal K(2k−1,j) and K(2k,j), is outputted from the color signal correction unit 335 in the color mode. The data selector 555 selects R″(2k−1,j), G″(2k−1,j) and B″(2k−1,j) at the odd-numbered pixel position, and R″(2k,j), G″(2k,j) and B″(2k,j) at the even-numbered pixel position in accordance with recognition signals of the odd/even number pixel positions in the main scanning direction from the timing generating circuit 355.

By using the color signal correction unit 335, it is possible to achieve improved gradation quality because the S/N ratio is improved from the equalization process despite the photo-induced discharge of the color filters. Further, even if the color filters are scanned in the sub scanning direction with the same speed as the monochrome filters, the deterioration of the color image quality can be minimized by the improvement of the S/N ratio resulting from the equalization process. Accordingly, it is possible to provide a moving mechanism in the sub scanning direction having a single speed, which allows for a simplified mechanism and drive circuit. The deterioration of the image quality caused by using the same speed to scan with the color and monochrome filters can be further compensated for with the compensation processing of the inter-line correction unit 330.

In an embodiment, the image reading apparatus 300 can be operated in three different modes. These three mode include color high accuracy, color high speed, and B/W (or monochrome). In the color high accuracy mode, the image reading apparatus 300 uses a low speed scan and no compensation or correction by the color signal correction unit 335. In the monochrome mode, the image reading apparatus 300 only uses the monochrome sensor of the image sensor unit 310 at a normal speed. In the color high speed mode, the image reading apparatus uses the color and monochrome sensors of the image sensor unit 310, scans at a normal speed, and uses the color signal correction unit 335 as described above with respect to FIGS. 3, 4, and 5. The reading speed in the color high speed mode and the monochrome mode can be the same, whereas the reading speed in the color high accuracy mode is lower, such as one half of the speed. In addition, a clock signal used in each mode may have the same frequency.

In the color high accuracy mode, priority is set on the color image quality by reducing the image reading speed in the sub scanning direction. In the color high speed mode, image quality is maintained by using the color signal correction unit 335 instead of reducing the image reading speed in the sub scanning direction. Since the reading speed and the image quality are inversely proportional, if reading is performed at a high speed, the S/N ratio of a photodiode is worsened. The color high speed mode uses image processing to compensate for the diminished S/N ratio.

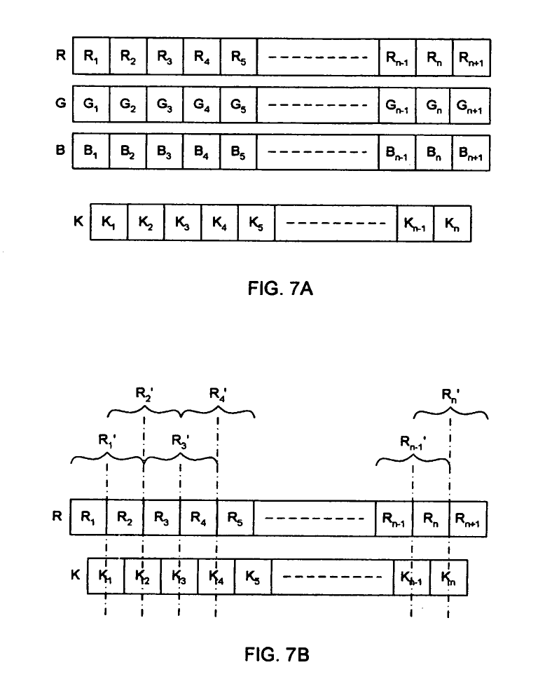

FIG. 7A depicts an alternative arrangement of the photodiode arrays of an image sensor unit consistent with the present invention. FIG. 7B is a graphical illustration of color pixel equalization using the alternative arrangement of photodiode arrays shown in FIG. 7A. As shown in FIG. 7A, the color (RGB) photodiode arrays are shifted from the monochrome (K) photodiode array by one half of a pixel. In addition, the number of photodiodes in the color photodiode arrays is greater than the number of photodiodes in the monochrome photodiode array. For example, if the monochrome photodiode array has n pixels, n being an integer, then the color photodiode arrays may have n+1 pixels.

As shown in FIG. 7B, each adjacent pair of the color pixel data is equalized. For example, in FIG. 7B, the R data is equalized by averaging the values for R₁ and R₂ to generate R₁′, averaging the values of R₂ and R₃ to generate R₂′, etc. As also shown in FIG. 7B, the equalized data R′ has a central axis aligned with the central axis of the monochrome data K.

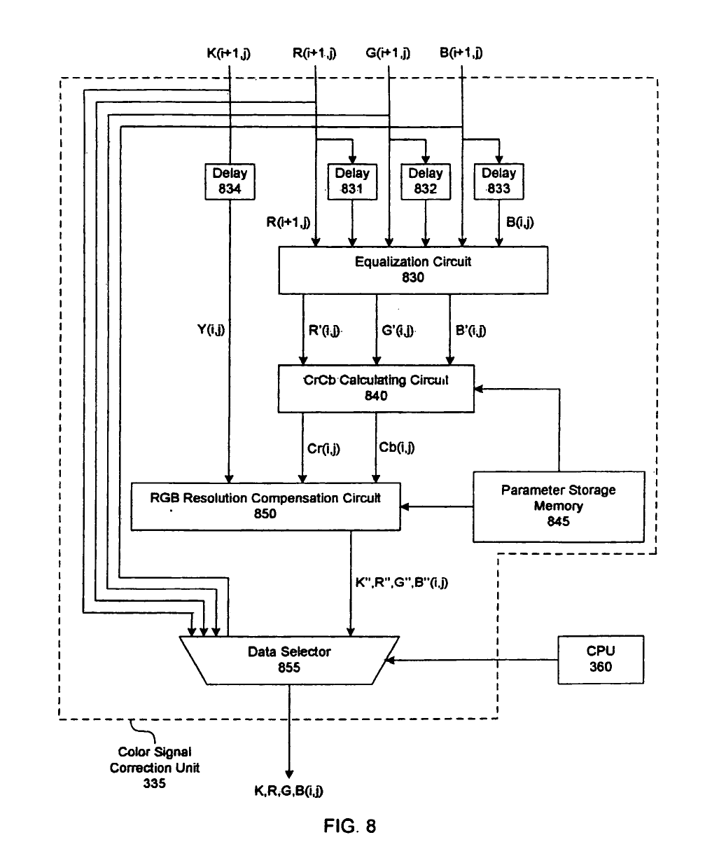

FIG. 8 is a block diagram of another color signal correction unit consistent with the present invention. The color signal correction unit of FIG. 8 is similar to the color signal correction unit of FIG. 5. Unless specified, any element in FIG. 8 in common with an element of FIG. 5 should be understood as being structured and operating in the same fashion as described above with respect to FIG. 5. As shown in FIG. 8, the color signal correction unit 335 comprises an equalization circuit 830, a CrCb calculating circuit 840, a RGB resolution compensation circuit 850, a parameter storage memory 845, 1-pixel delay buffers 831-834, and a data selector 855.

In the color signal correction unit 335 of FIG. 8, the B/W pixel data K(i+1,j) and the color pixel data R(i+1,j), G(i+1,j), and B(i+1,j) are received from the inter-line correction unit 330. The equalization circuit 830 and the 1-pixel delay buffers 831-833 perform equalization processing in accordance with the formulas (14)-(16). That is, as graphically shown in FIG. 7B, the formulas convert each of the color pixel data into a moving average of each pair of adjacent pixels.
R′(i,j)=(R(i,j)+R(i+1,j))/2 (14)
G′(i,j)=(G(i,j)+G(i+1,j))/2 (15)
B′(i,j)=(B(i,j)+B(i+1,j))/2 (16)

The equalization performed by the equalization circuit 830 improves the S/N ratio of the color pixel data that is otherwise diminished because of the shortage of luminous energy. Further, since the phase of color data is shifted by half of a pixel in the main scanning direction, the center location of the equalized color data R′(i,j), G′(i,j), B′(i,j), and the monochrome data K(i,j) match, as shown in FIG. 7B. The present equalization approach performed on the color data results in the resolution of the equalized color data R′(i,j), G′(i,j), B′(i,j) matching the resolution of the monochrome data K(i,j).

The CrCb calculating circuit 840, in conjunction with the 1-pixel delay buffer 834, perform the YCrCb conversion shown in formulas (17)-(19). These formulas convert the color and monochrome data into a luminance signal Y, a first color-difference signal Cr (R-Y component), and a second color-difference signal Cb (B-Y component).
Y(i,j)=K(i,j) (17)
Cr(i,j)=aᵣ₀R′(i,j)+a_{g0}G′(i,j)+a_{b0}B′(i,j) (18)
Cb(i,j)=aᵣ₁R′(i,j)+a_{g1}G′(i,j)+a_{b1}B′(i,j) (19)

Since the B/W signal K can be treated as a luminance signal Y, the luminance signal Y(i,j) corresponding to formula (17) can be inputted into the RGB resolution compensation circuit 850 by delaying the inputted B/W signal K(i+1,j) for 1 pixel length with the 1-pixel delay buffer 834. The first color-difference signal Cr and the second color-difference signal Cb can be formed from a signal of equalized color data as shown in formulas (18) and (19), even if there is no luminance signal. By calculating formulas (18) and (19) using the parameters aᵣ₀, a_{g0}, a_{b0}, aᵣ₁, a_{g1}, and a_{b1} stored in the parameter storage memory 845, the CrCb calculating circuit 840 obtains the pixel data Cr(i,j) of the first color-difference signal and the pixel data Cb(i,j) of the second color-difference signal, and inputs them into the RGB resolution compensation circuit 850.

The RGB resolution compensation circuit 850 executes RGB inverse transformation according to formulas (20)-(22), in order to obtain the converted three primary colors R″, G″ and B″.
R″(i,j)=bₖ₀K(i,j)+bᵣ₀Cr(i,j) (20)
G″(i,j)=bₖ₁K(i,j)−bᵣ₁Cr(i,j)+b_{b0}Cb(i,j) (21)
B″(i,j)=bₖ₂K(i,j)+b_{b1}Cb(i,j) (22)

The RGB resolution compensation circuit 850 can calculate the formulas (20)-(22) almost in parallel using the parameters bₖ₀, bₖ₁, bₖ₂, bᵣ₀, bᵣ₁, b_{b0}, and b_{b1} that are stored in the parameter storage memory 845. The RGB resolution compensation circuit 850 provides the color pixel data R″(i,j), G″(i,j), and B″(i j), which are obtained according to the formulas (20)-(22), along with the monochrome pixel data K″(i,j) to the data selector 855.

The foregoing description of preferred embodiments of the invention has been presented for purposes of illustration and description. It is not intended to be exhaustive or to limit the invention to the precise form disclosed, and modifications and variations are possible in light in the above-teachings or may be acquired from practice of the invention. The embodiments (which can be practiced separately or in combination) were chosen and described in order to explain the principles of the invention and as practical application to enable one skilled in the art to utilize the invention in various embodiments and with various modifications are suited to the particular use contemplated. It is intended that the scope of the invention be defined by the claims appended hereto and their equivalents.

What is claimed is:

1. A method for processing image data, comprising:
generating color image data and monochrome image data from an original image, the color image data and the monochrome image data having a first resolution, the color image data including RGB data;
averaging multiples of pixels of the color image data, the averaged pixel data having a second resolution lower than the first resolution based on the multiples;
generating color difference data using the averaged pixel data; and
generating compensated color image data having the first resolution based on the color difference data and the monochrome image data.

2. A method according to claim 1, wherein the multiple is two, and the step of averaging multiples of pixels includes averaging respective adjacent pairs of pixels of the color image data, each respective adjacent pair of pixels having pixels different from each other respective adjacent pair of pixels.

3. A method according to claim 2, wherein the step of averaging respective adjacent pairs of pixels of the color image data includes calculating the averaged pixel data according to the following expressions:
R′(k,j)=[R(2k−1,j)+R(2k,j)]/2;
G′(k,j)=[G(2k−1,j)+G(2k,j)]/2;
B′(k,j)=[B(2k−1,j)+B(2k,j)]/2,
wherein R′, G′, and B′ are the averaged pixel data for the RGB data, k is the column number, and j is the row number.

4. A method according to claim 3, wherein the step of generating color difference data includes calculating the color difference data according to the following expressions:
Cr(k,j)=aᵣ₀R′(k,j)+a_{g0}G′(k,j)+a_{b0}B′(k,j);
Cb(k,j)=aᵣ₁R′(k,j)+a_{g1}G′(k,j)+a_{b1}B′(k,j);
wherein Cr is a first color difference signal, Cb is a second color difference signal, and aᵣ₀, a_{g0}, a_{b0}, aᵣ₁, a_{g1}, and a_{b1} are color difference coefficients.

5. A method according to claim 4, wherein the step of generating compensated color image data includes calculating the compensated color image data according to the following expressions:
R″(2k−1,j)=bₖ₀K(2k−1,j)+bᵣ₀Cr(k,j)
G″(2k−1,j)=bₖ₁K(2k−1,j)−bᵣ₁Cr(k,j)+b_{b0}Cb(k,j)
B″(2k−1,j)=bₖ₂K(2k−1,j)+b_{b1}Cb(k,j)
R″(2k,j)=bₖ₀K(2k,j)+bᵣ₀Cr(k,j)
G″(2k,j)=bₖ₁K(2k,j)−bᵣ₁Cr(k,j)+b_{b0}Cb(k,j)
B″(2k,j)=bₖ₂K(2k,j)+b_{b1}Cb(k,j)
wherein R″, G″ and B″ are the compensated color image data, K is the monochrome image data, and bₖ₀, bₖ₁, bₖ₂, bᵣ₀, bᵣ₁, b_{b0}, and b_{b1} are color compensation coefficients.

6. A method according to claim 2, wherein the averaged pixel data has half as many pixels as the color image data.

7. A method according to claim 1, wherein the monochrome image data and the color image data have the same number of pixels.

8. A method according to claim 1, wherein the compensated color image data includes odd pixel data and even pixel data, the method further comprising:
generating an odd/even pixel recognition signal having a first level and a second level different from the first level;
outputting the odd pixel data when the odd/even pixel recognition signal is at the first level; and
outputting the even pixel data when the odd/even pixel recognition signal is at the second level.

9. A method for processing image data, comprising:
generating color image data and monochrome image data from an original image, the color image data and the monochrome image data having a first resolution, the color image data including RGB data, each line of the color image data having a first number of pixels, and each line of the monochrome image data having a second number of pixels less than the first number of pixels;
averaging multiples of pixels of the color image data, the averaged pixel data having the first resolution, and each line of the averaged pixel data having the second number of pixels;
generating color difference data using the averaged pixel data; and
generating compensated color image data having the first resolution based on the color difference data and the monochrome image data.

10. A method according to claim 9, wherein the multiple is two, and the step of averaging multiples of pixels includes averaging adjacent pairs of pixels of the color image data, each adjacent pair of pixels having one pixel in common with two other adjacent pairs of pixel.

11. A method according to claim 10, wherein the step of averaging adjacent pairs of pixels of the color image data includes calculating the averaged pixel data according to the following expressions:
R′(i,j)=(R(i,j)+R(i+1,j))/2
G′(i,j)=(G(i,j)+G(i+1,j))/2
B′(i,j)=(B(i,j)+B(i+1,j))/2
wherein R′, G′, and B′ are the averaged pixel data for the RGB data, i is the column number, and j is the row number.

12. A method according to claim 11, wherein the step of generating color difference data includes calculating the color difference data according to the following expressions:
Cr(i,j)=aᵣ₀R′(i,j)+a_{g0}G′(i,j)+a_{b0}B′(i,j)
Cb(i,j)=aᵣ₁R′(i,j)+a_{g1}G′(i,j)+a_{b1}B′(i,j)
wherein Cr is a first color difference signal, Cb is a second color difference signal, and aᵣ₀, a_{g0}, a_{b0}, aᵣ₁, a_{g1}, and a_{b1} are color difference coefficients.

13. A method according to claim 12, wherein the step of generating compensated color image data includes calculating the compensated color image data according to the following expressions:
R″(i,j)=bₖ₀K(i,j)+bᵣ₀Cr(i,j)
G″(i,j)=bₖ₁K(i,j)−bᵣ₁Cr(i,j)+b_{b0}Cb(i,j)
B″(i,j)=bₖ₂K(i,j)+b_{b1}Cb(i,j)
wherein R″, G″ and B″ are the compensated color image data, K is the monochrome image data, and bₖ₀, bₖ₁, bₖ₂, bᵣ₀, bᵣ₁, b_{b0}, and b_{b1} are color compensation coefficients.

14. A method according to claim 9, wherein the first number of pixels is one more than the second number of pixels.

15. A method according to claim 9, wherein the color image data and the monochrome image data are generated by a color photodiode array and a monochrome photodiode array, respectively.

16. A method according to claim 15, wherein the photodiodes of the color photodiode array are shifted by one half of a pixel from the photodiodes of the monochrome photodiode array.

17. A method according to claim 16, wherein a central axis of the averaged pixel color data is aligned with a central axis of the monochrome image data.

18. An apparatus for processing image data, comprising:
a scanner that generates color image data and monochrome image data from an original image, the color image data and the monochrome image data having a first resolution, the color image data including RGB data
an image processor, coupled to the scanner, that receives the color image data and the monochrome image data, the image processor configured to:
average multiples of pixels of the color image data, the averaged pixel data having a second resolution lower than the first resolution based on the multiples;
generate color difference data using the averaged pixel data; and
generate compensated color image data having the first resolution based on the color difference data and the monochrome image data.

19. A method for processing image data, comprising:
receiving an indication to process image data in a first, second, or third mode;
if the received indication is the first mode, then generating color image data and monochrome image data from an original image scanned with color sensors and a monochrome sensor at a first speed lower than a second speed;
if the received indication is the second mode, then generating monochrome image data from the original image scanned only with the monochrome sensor at the second speed; and
if the received indication is the third mode, then:
generating color image data and monochrome image data from an original image scanned at the second speed, the color image data and the monochrome image data having a first resolution;
averaging multiples of pixels of the color image data, the averaged pixel data having a second resolution lower than the first resolution based on the multiples;
generating color difference data using the averaged pixel data; and
generating compensated color image data having the first resolution based on the color difference data and the monochrome image data.
